(19) United States
(12) Patent Application Publication
(10) Pub. No.: US 2024/0243237 A1
(43) Pub. Date: Jul. 18, 2024

(54) DISPLAY ELEMENT AND METHOD

(71) Applicant: ams-OSRAM International GmbH, Regensburg (DE)

(72) Inventors: Michael WITTMANN, Alteglofsheim (DE); Simon SCHWALENBERG, Brennberg (DE)

(21) Appl. No.: 18/562,277

(22) PCT Filed: May 17, 2022
(86) PCT No.: PCT/EP2022/063312

§ 371 Date: Nov. 17, 2023

(30) Foreign Application Priority Data
May 19, 2021 (DE) 10 2021 113 047.6

(51) Int. Cl. H01L 33/50; H01L 33/60

(52) U.S. Cl. CPC H01L 33/505; H01L 33/60

(57) ABSTRACT

A display element includes a carrier element on which at least one optoelectronic component for generating light of a first wavelength is arranged with a light emission side. The light emission side defines a main emission direction. The at least one optoelectronic component is connected to a plurality of connection lines on the carrier element. The display element also includes a molded body forming a symbol element. The molded body includes at least one recess and is connected to the carrier element such that the at least one optoelectronic component is in the at least one recess. A space formed by the recess is between the light exit side of the at least one optoelectronic component and the molded body. The symbol element is visible to a user in a top view of the display element when the at least one optoelectronic component is switched off.

The present application claims the priority of the German first filing DE 10 2021 113 047.6 of May 19, 2021, the disclosure of which is hereby incorporated by reference in its entirety.

The present invention relates to a display element. The invention further relates to a method of manufacturing such a display element.

### BACKGROUND

Due to the increasing miniaturization of LED technology, there are many possibilities for implementing display elements. Well-known forms use μ-LED-based displays for this purpose. In this case, μ-LEDs are optoelectronic components that are characterized by a very small edge length in the range of a few μm to around 100 μm. In addition to the effort involved in manufacturing such displays, they are often very expensive and complex due to the active control required (TFT backplane & control electronics). Furthermore, they are usually rectangular in shape and therefore limited in terms of their application possibilities.

There is therefore a need to create operating elements that can be used in a variety of different ways and yet are cheaper to manufacture than conventional technologies.

### SUMMARY OF THE INVENTION

This need is met by the objects of the independent patent claims. Further developments and embodiments are the subject of the dependent claims.

The inventors have recognized that although display elements are used in many areas, they are often not always easy to recognize, especially when switched off. Other operating elements are easy to recognize, but are purely passive, i.e. they cannot switch between a switched-off and switched-on state. If such elements are also designed as part of the glazing, it is necessary to create a trade-off. On the one hand, transparency should be as good as possible so that a person can look through the glazing without being impaired in their view by the display elements.

Applications for such display elements can be found in the automotive sector, for example, in vehicle functions for cars, buses or other vehicles. In the field of buildings, these would be display symbols such as emergency exits or illuminated controllers that enable regulation. Other such display elements can be found in automation and industrial technology, in aircraft construction and also in home appliances. In all these applications, an operating function can also be installed in addition to the display function.

According to some aspects, a display element comprises a carrier element on which at least one optoelectronic component for generating light of a first wavelength is arranged with a light emission side. The light emission side defines a main emission direction. The at least one optoelectronic component is connected to several connection lines on the carrier element. Furthermore, a molded body forming a symbol element is provided, which comprises at least one recess and is connected to the carrier element in such a way that the at least one optoelectronic component is arranged in the at least one recess. According to the proposed principle, a space formed by the recess should be present between the light-emitting side of the at least one optoelectronic component and the molded body. The symbol element formed by the molded body is visible to a user in a top view of the display element when the at least one optoelectronic component is switched off. In some aspects, the shape of the recess follows the shape of the symbol element. In other words, the symbol element is formed by the recess in which the component is arranged.

The display element provided in this way can be easily inserted into or attached to panes or glazing. Due to the molded body, the display element remains visible even when switched off. Nevertheless, a high luminance is provided when switched on and a very small installation depth is possible. This means that the display element can also be used in laminated glass panes. Touch functionality is also possible in combination with touch-sensitive sensors.

In a further aspect, the carrier element comprises a plurality of optoelectronic components. At the same time, the molded body forming the symbol element also has a number of recesses corresponding to the plurality of optoelectronic components. An optoelectronic component can now be arranged in a recess of the number of recesses corresponding to the plurality of optoelectronic components. This means that the shape of the symbol element can also be simulated by the position of the optoelectronic components on the carrier element.

Alternatively, two or more optoelectronic components can also be arranged in the at least one recess in the molded body, so that the space forming the recess is formed between the light-emitting side of the two optoelectronic components and the molded body. In this case, a larger recess is thus provided in the molded body so that several components fit into it.

In addition to the gap between the light-emitting surface and the material of the recess, the side surfaces of the at least one optoelectronic component can also be spaced from a side surface of the recess, forming a gap. This makes it possible to compensate for manufacturing tolerances and also tolerances in the positioning of the molded body on the carrier element or the optoelectronic components on the carrier. In addition, such distances between the side surfaces are useful if the symbol is depicted by the recess. In some aspects, the distance of the side surfaces between the component and the recess essentially corresponds to the height of the molded body above the component. In other words, the surfaces of the component are substantially equidistant from the respective opposite surfaces of the recess.

In some aspects, the space formed by the recess comprises a height of 20 μm to 100 μm and in particular a height in the range of 40 μm to 60 μm. With respect to a gap towards the side walls, this distance may be in the same order of magnitude but may also be greater, for example in the range of 100 μm to 300 μm. In this regard, in some aspects it is provided that the at least one optoelectronic component comprises an edge length in the range of less than 500 μm and in particular less than 200 μm and in particular less than 100 μm. In some aspects, the component is designed as a horizontal light-emitting diode. It is also possible to design it as a vertical light-emitting diode, with a feed line leading to the light emission side.

In some aspects, the molded body comprises diffusion particles, in particular TiO2, Al2O3, PMMA or PC. These can either be essentially uniformly distributed in the molded body. However, the concentration of the diffusion particles in the molded body can also change with increasing distance from the at least one optoelectronic component and, for example, also increase. This improves the homogeneity during the illumination of the molded body and thus of the symbol element.

In another aspect, the shaped body also comprises absorber particles, in particular soot particles. These can also be essentially uniformly distributed. Again alternatively, converter particles may be provided in the molded body, which are distributed substantially uniformly in the molded body and are designed to convert light emitted by the least one optoelectronic component into light of a different wavelength. Like the other particles, the concentration of the converter particles in the molded body can change in some aspects with increasing distance from the at least one optoelectronic component. The different particles can also be combined with each other depending on the application.

Another aspect is concerned with improving contrast and homogeneity. In some aspects, the outer side walls of the molded body and thus the boundary walls of the symbol element are designed with a roughening or a reflective material. As a result, light is not coupled out but remains in the symbol element, which improves homogeneity and illumination. In some further aspects, a reflective layer can also be provided between the carrier element and the molded body, at least in partial areas. Similarly, the side walls of the recess may comprise a reflective layer. Instead of a reflective material or corresponding layers, black or absorbent layers can also be used.

Among other things, an adhesive is suitable for attaching the molded body to the carrier element. This is designed to be reflective in some aspects, so that the radiation characteristics and visibility are improved.

Since the light emission side is at a distance from the material of the recess, reflections can occur at the interface. In order to reduce these, in some aspects the side of the recess opposite the light exit side of the at least one optoelectronic component can comprise a curved shape. For this purpose, the intermediate space is filled with a medium, in particular with a gas such as air or nitrogen, which comprises a lower refractive index than the material of the molded body.

In some aspects, the at least one optoelectronic component is configured to generate light of one color or to generate light of at least two colors, in particular green and/or red.

Another aspect concerns the method for forming a display element. There are several possibilities for this. In some aspects, optoelectronic components, in particular light-emitting diodes, are applied to transparent or semi-transparent substrates as carriers with conductive structuring and attached thereto. A molded body (in the form of the symbol to be displayed) with cavities is then positioned on the substrate and placed at the locations equipped with LEDs, with the LEDs being arranged in the respective recesses or in the recess. The display element created in this way can then be inserted as a laminate between other panes.

In another aspect, a carrier element is provided on which at least one optoelectronic component for generating light of a first wavelength is arranged with a light emission side. The light emission side defines a main emission direction. The carrier element also comprises a plurality of connection lines which are connected to the at least one optoelectronic component for supplying it.

A molded body is then provided, which forms a symbol element, wherein the molded body comprises at least one recess. The molded body is positioned on the carrier element in such a way that the at least one optoelectronic component is arranged in the at least one recess. The molded body is then attached to the carrier element so that a gap formed by the recess is present between the light-emitting side of the at least one optoelectronic component and the molded body. The symbol element formed by the molded body remains visible to a user in a top view of the display element even when the at least one optoelectronic component is switched off. In some aspects, the symbol element is provided by the shape of the recess.

In a further alternative method, an air gap or a gap is created over optoelectronic components mounted on a carrier by laminating a spacer film with recesses on the carrier. The recesses are at the points that have been or are to be fitted with optoelectronic components. A structured diffuser film is then applied, in which the structure of the film forms the symbol element. The structured diffuser foil is suitably positioned so that the structure lies at least partially over the recess or recesses. In all these embodiments and aspects disclosed herein, a layer can also be present on the molded body that implements a touch-sensitive sensor. This layer can be provided on the side of the molded body facing away from the light emission side, but also on the side facing the light emission side.

In a further aspect, the side walls of the molded body can be provided with a roughening or a reflective material. Alternatively, an absorbent or black layer can be provided instead of a reflective layer. This also increases the contrast and creates improved visibility of the symbol element when looking at the glazing.

In one aspect, an adhesive, in particular an adhesive with reflective particles, is applied to the carrier element or the molded body and the molded body and carrier element are then intimately bonded together.

In some aspects, an injection molding process is used to produce the molded body. Each molded body can be produced individually. However, it is also possible to produce them in larger numbers and then separate them. In addition, diffuser particles and/or converter particles can be introduced during the injection molding process, whereby a concentration of the diffuser particles and/or converter particles changes with increasing distance from the LED and, in particular, increases.

### BRIEF DESCRIPTION OF THE DRAWING

Further aspects and embodiments according to the proposed principle will become apparent with reference to the various embodiments and examples described in detail in connection with the accompanying drawings.

FIGS. 1A to 1C show a first embodiment of a control element with some aspects according to the proposed principle;

FIGS. 2A to 2C show various aspects of the proposed principle in a second embodiment;

FIG. 3 illustrates a further embodiment of a display element according to some aspects of the proposed principle;

FIG. 4 shows a fourth embodiment of a display element with some aspects according to the proposed principle;

FIG. 5 shows a fifth embodiment of a display element with some aspects according to the proposed principle;

FIG. 6 shows a top view of a sixth embodiment of a display element with some aspects according to the proposed principle;

FIG. 7 shows a cross-sectional view of a seventh embodiment of a display element with some aspects according to the proposed principle;

FIG. 8 shows an embodiment of a control element with some aspects according to the proposed principle;

FIG. 9 shows a version of a control element in various operating states to illustrate some aspects of the proposed principle;

FIG. 10 illustrates an example of a method for manufacturing a display element with some aspects according to the proposed principle;

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects comprise a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. Thus, it is possible to derive such relationships between the elements based on the figures. However, the proposed principle is not limited to this, but various optoelectronic components with different sizes and also functionality can be used in the invention. In the embodiments, elements with the same or similar effects are shown with the same reference signs.

Nowadays, many applications require display and operating elements to be provided on transparent surfaces. The focus here is on making optimum use of the available space without obstructing the user's view through the transparent surface of a windshield, for example. Roof consoles in the automotive sector are a typical example of display and control elements in the area of such transparent surfaces. In buses or trains, such display and control elements can be used for doors in their glazing. Here it is necessary that the contour, i.e. the control element, can be recognized well enough not only in the dark, but also in daylight. In aircraft construction, in automation and industrial technology as well as in various home appliances or for consumer electronics, it is also useful to arrange display and control elements on transparent surfaces. However, the currently common design of such display and control elements leads to an impairment of the field of vision, as mainly non-transparent components are used, which are also raised so that they can be felt. The design options are also limited, as the display and control elements usually follow fixed shapes.

The inventors have set themselves the goal of realizing cost-effective and partially transparent and filigree display elements so that these can also be used on transparent surfaces without the disadvantages listed above. At the same time, the disadvantages that occur with so-called transparent displays are to be avoided. These include the complex control by means of a TFT backplane or control electronics and often the optoelectronic components, which are superfluous depending on the display and operating elements and are therefore not required. Nevertheless, due to the various possible applications mentioned above, it is necessary to keep the control element flexible so that it can be applied not only to smooth and straight transparent surfaces, but also to curved surfaces, for example.

The inventors are now proposing to improve the integration of display elements or operating elements, for example in the upper part of windscreens, door glazing or other transparent surfaces, so that a high level of transparency is achieved on the one hand and the symbol element is also recognizable when switched off on the other.

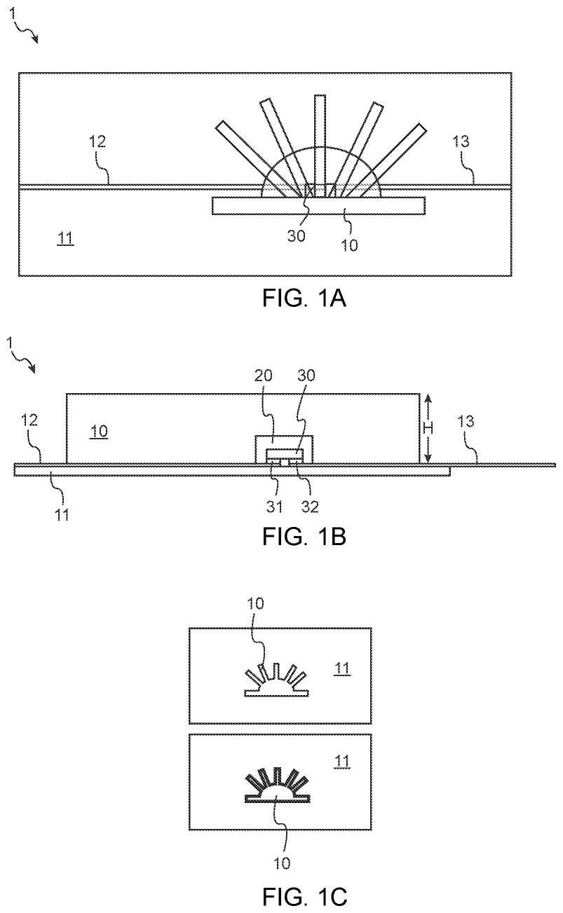

FIGS. 1A and 1B show a first embodiment of the proposed principle in plan view and in cross-sectional view, respectively. In the present example, the display element 1 comprises a carrier 11 with one or more supply lines 12 and 13 arranged thereon. As shown in FIG. 1A, the two supply lines 12 and 13 are arranged longitudinally, i.e. they run from the left side over the carrier 11 to the right side. An optoelectronic semiconductor component 30 is arranged between the two supply lines in the plan view. The cross-sectional view according to FIG. 1B shows that the optoelectronic semiconductor component 30 is designed as a horizontal light-emitting diode with two contact pads 31 and 32. The two contact pads 31 and 32 are arranged on a side of the semiconductor component 30 facing away from the main radiation direction. Contact pad 31 contacts the supply line 12 and contact pad 32 is connected to the supply line 13. In addition to the supply lines 12 and 13 shown in FIGS. 1A and 1B, other control lines can also be connected to the optoelectronic semiconductor component.

The display element 1 according to the proposed principle also comprises a molded body 10 made of a plastic, which is designed as a semicircular sun as shown in the top view of FIG. 1A. The molded body 10 thus represents a symbol element which is intended to communicate certain information to an observer depending on the state of the semiconductor component. The molded body 10 is made of a transparent plastic such as PVP, PVC, PE or PP. Silicone-based plastics can also be used for the molded body 10.

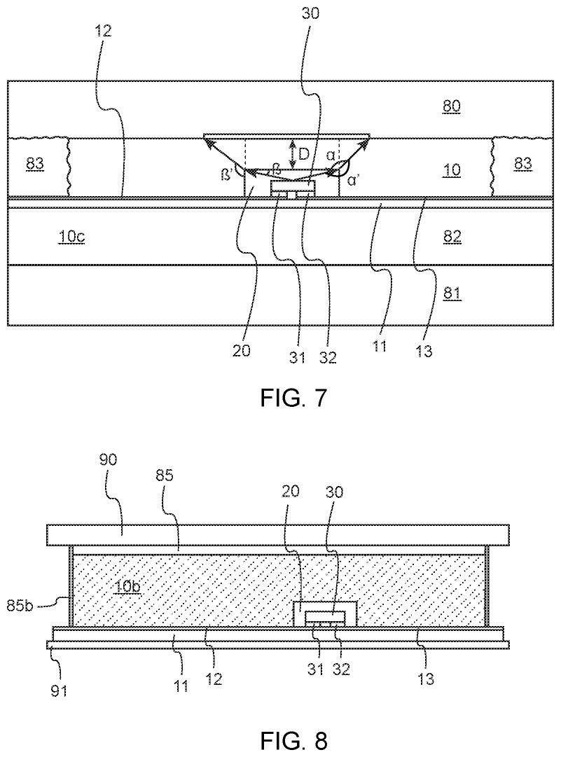

The cross-sectional view of FIG. 1B shows that the molded body 10 comprises a recess or cavity 20. The molded body 10 is positioned on the carrier 11 in such a way that the optoelectronic semiconductor component 30 is placed in the recess and cavity 20. For this purpose, the cavity 20 is slightly larger so that a space is formed between it and the respective side surfaces of the semiconductor component 30. Furthermore, the recess is designed with regard to its depth in such a way that a gap is created between the surface of the semiconductor component 30, which forms the light-emitting side, and the material of the molded body 10. In other words, the cavity 20 is thus designed to be larger than the semiconductor component 30, so that the latter has sufficient space in the recess. On the one hand, this has the advantage that manufacturing tolerances and fluctuations in the position of the semiconductor component or the molded body can be compensated for. On the other hand, a light-emitting surface on the upper side of the optoelectronic semiconductor component results in additional radiation properties, as explained in more detail in FIG. 7 below. In addition, the recess can also simulate the symbol element of the molded body.

The molded body 10 has a certain height H, which varies depending on the desired application. In addition, the molded body 10 has a slightly different color or a slightly different transparent property, so that it differs from the carrier 11 in plan view, as shown in FIGS. 1A and 1C. An additional transparent layer (not shown here) can be designed around the molded body so that the molded body 10 is embedded in this layer.

FIG. 1C shows an embodiment in a switched-off or switched-on state of the optoelectronic semiconductor component. In the upper partial image of FIG. 1C, the top view of the molded body 10 is shown in a switched-off state of the semiconductor device. Due to the different materials used and slightly different transparent properties, the semi-circular sun symbol element shown and visible on the molded body results. This is characterized by a different color or a different visible property, so that a user can also see the switched-off symbol on a pane of glass or between two panes of glass. In the second partial image below, the optoelectronic component is switched on and illuminates the shaped body accordingly.

Depending on the design of the optoelectronic component, this can be monochrome, but also more colored or mixed colored light.

In this way, a display element is created which can be easily embedded between windscreens or glass panes and provides the user with different information depending on the state of the component. Nevertheless, the display element remains visible to the user even when it is switched off due to the molded body.

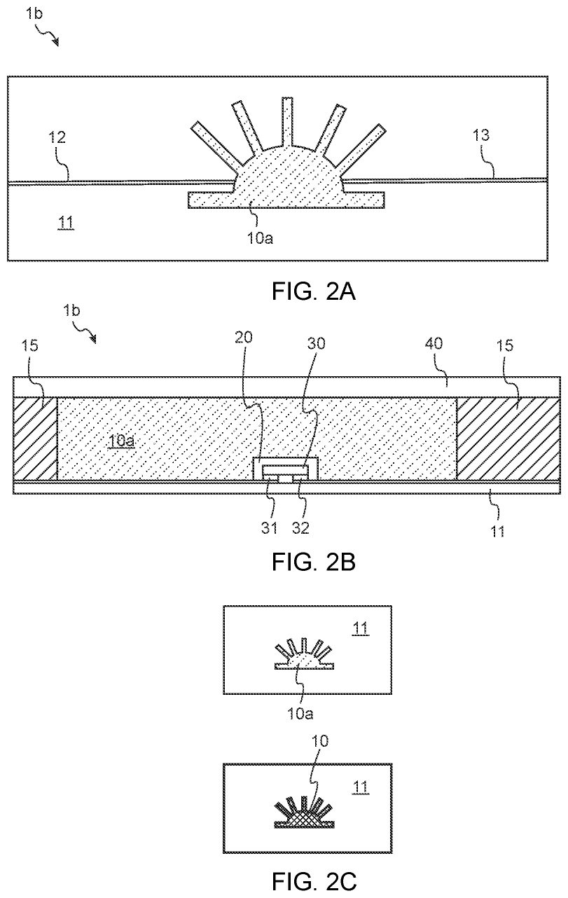

FIGS. 2A, 2B and 2C show a further embodiment of a display element based on the proposed principle. The display element 1B is here again designed with a sun-shaped symbol element as a molded body 10a. In contrast to the embodiment in sub-FIGS. 1A to 1C, here the molded body 10a is additionally filled with converter particles. The converter particles are used to convert the light of a first wavelength emitted by the optoelectronic semiconductor component 30 into light of a second wavelength. For example, the optoelectronic semiconductor component emits blue light during operation, which is absorbed by the converter particles and re-emitted as light of a longer wavelength, for example in the red range.

The display element 1b is constructed in a similar way to the display element in FIGS. 1A to 1C. It comprises a carrier 11 on which several supply lines 12 and 13 are arranged and connected to an optoelectronic component 30 as a horizontal light-emitting diode. The optoelectronic semiconductor component 30 is arranged in a cavity 20 of the molded body 10a so that a small gap remains between all sides and also the surface. The side walls of this cavity are spaced at the same distance from the side walls of the component as the surface of the component is from the surface of the cavity lying in the main emission direction. To create a planar surface, the molded body is also surrounded by a transparent material 15, so that a plane-parallel surface is created between the molded body 10a and the additional material 15. The planar surface can be created by filling and then sanding or removing until the surface is planar. A transparent glass pane 40 is now applied to this surface so that the display element is arranged directly on the pane 40.

Not shown here is a second pane of glass on which the carrier 11 can be arranged. In this way, the display element 1b would be embedded between one or more glass panes according to the proposed principle. Due to the additional converter particles in the shaped body 10a, the display element according to the invention appears in a slightly reddish color even when switched off, as shown in the top view of FIG. 2C. If other conversion dyes are used, a different color impression may result in the switched-off state. For example, a yellow conversion dye that is illuminated by a blue LED is often used for white conversion. When switched off, the yellow conversion particles would therefore produce a yellowish hue.

This makes it stand out clearly from the surrounding transparent material 15 and the carrier element 11, so that the symbol element remains clearly visible to a user even when it is switched off. When switched on, the optoelectronic semiconductor component generates light, which is absorbed by the converter particles within the molded body 10a and converted into light of the second wavelength. Accordingly, the symbol element illuminates either in the case of a complete conversion in light with the second wavelength or in the case of only partial conversion in a corresponding mixed light. The thickness of the molded body or the concentration of the particles is selected accordingly to ensure complete or partial conversion. For example, the shaped body can contain converter particles for the conversion of blue light, so that the symbol element as a whole shines in a white color as a mixed color of blue and yellow components.

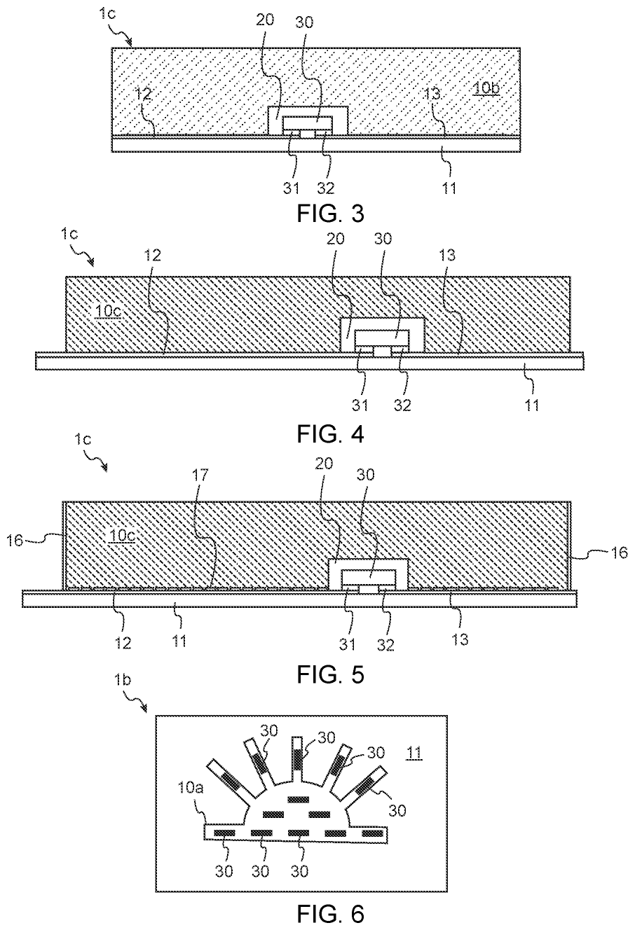

FIG. 3 shows a cross-sectional view of a further embodiment of a display element based on the proposed principle. In this case, diffuser particles in combination with absorber particles are introduced into the molded body. The absorber or diffuser particles can comprise, for example, titanium oxide or soot particles or other materials. The diffuser particles introduced ensure that the light emitted by the optoelectronic semiconductor component is evenly distributed in the molded body and thus over the symbol. This makes it possible for even delicate symbol structures to be sufficiently well illuminated so that a user can easily recognize the shape of the symbol element both when it is switched off and when it is switched on.

A shaped body 10b with diffuser particles is therefore particularly useful if the symbol has a more complex design. For example, the semi-circular sun shown in the previous figures comprises numerous radiating elements. These are embedded in an enclosing material with a different refractive index. Together with the diffuser particles in the molded body, this results in uniform illumination due to wave guidance, even in the more delicate areas of the symbol. At the same time, the diffuser particles make the symbol stand out better from its surroundings even when it is switched off.

FIG. 4 shows a further embodiment in which the molded body 10c is filled with a pure diffuser. The molded body 10c encloses an optoelectronic semiconductor component 30 on a carrier 11 with a cavity 20. As shown in FIGS. 2 and 3, the corresponding diffuser particles are homogeneously introduced into the molded body and distributed there. However, it is possible to distribute both diffuser particles and converter particles or absorber particles homogeneously in terms of concentration in the molded body according to the configuration. This makes it possible to produce the molded body together with the diffuser particles in a simple injection molding process. Here too, the component is arranged in the cavity in such a way that all surfaces comprise the same distance from the boundary surfaces of the cavity.

However, a somewhat more complex process can also consist of distributing the particles inhomogeneously, i.e. with a concentration gradient in the molded body. For example, the molded body shown in FIG. 4 is designed with such a diffusion gradient with regard to the diffuser particle concentration, so that the particle concentration increases with the distance to the LED. This achieves improved homogeneity in the illumination. Such an inhomogeneous distribution is particularly useful for filigree structures similar to the design form in plan view in FIGS. 1A and 1B in order to achieve good homogeneity in the illumination even in the filigree partial areas of the symbol element. Such an inhomogeneous distribution can be created during the production of the molded body. For this purpose, diffuser particles as well as converter particles or absorber particles with an inhomogeneous distribution can be introduced into the molded body.

An improved embodiment shows the arrangement of a display element 1c as shown in FIG. 5. In this embodiment, an additional reflective layer 17 is applied to the base of the carrier element 11 in the area of the molded body. This can, for example, be a reflective layer made of silver or another material. The layer can also be applied to the molded body during manufacture. Alternatively, the reflective layer can also be formed by an adhesive with reflector particles. The adhesive layer is applied to the carrier during production and the molded body is arranged and attached to it. The reflective layer 17 on the surface of the carrier is electrically insulated from the two supply lines 11 and 12 so as not to cause a short circuit. The reflective layer 17 is arranged between the molded body 10c and the carrier, which is designed with additional diffuser particles as in the previous example in FIG. 4.

In addition, however, the side areas of the molded body 10c are also manufactured with a reflective layer 16. As a result, light is reflected from the sides and the bottom area of the molded body so that a symbol with very precise edges is visible during operation of the optoelectronic semiconductor device 30. Compared to the previous examples, the reflective layers, particularly on the side surfaces of the molded body 10c, have the advantage that crosstalk of light out of the molded body into the surrounding material is avoided. The symbol is therefore much more precise and clearly visible when switched on.

FIG. 6 shows a further embodiment here with the use of so-called μ-LEDs. μ-LEDs are optoelectronic semiconductor components that are characterized by particularly small dimensions in the range of a few 10 μm. This means that such designs are also suitable for molded bodies with particularly filigree structures. As shown in FIG. 6 in plan view, the carrier 11 comprises several optoelectronic components 30, which are arranged at predetermined positions with respect to the carrier. In particular, these optoelectronic semiconductor bodies mimic the symbol element of the molded body in terms of their shape and positioning on the surface of the carrier. Each of these optoelectronic semiconductor components is in turn arranged in a recess of the molded body. This molded body also imitates the symbol, so that it is also visible in a configured state via the “negative”, so to speak, i.e. through the cavity in the molded body. By using several optoelectronic components, a significantly improved, more uniform and brighter illumination of the symbol element can be achieved when it is switched on. In addition, even if one of the components is damaged or fails, the symbol can still be recognized sufficiently well by a user when switched on.

As already mentioned at the beginning, the cavity 20 within the molded body and in particular the distance between the light-emitting side of the optoelectronic semiconductor device 30 and the top surface of the material of the molded body allows a certain amount of light guidance when switched on.

FIG. 7 shows such an embodiment to explain the essential aspects of the proposed principle and the embodiments set out here. In this embodiment example, the display element 1 is embedded between two glass layers or glass plates 80 and 81. A PVB layer 82 is applied to a first glass plate 81. This is transparent. The carrier element 11 is arranged on the PVB layer 83 and the supply lines 12 and 13 are applied to its surface.

As shown, the leads electrically connect an optoelectronic semiconductor component 30. For this purpose, the respective leads 12 and 13 are connected to the contact pads 31 and 32 of the optoelectronic semiconductor component 30.

The optoelectronic semiconductor component 30 is arranged in a cavity 20 of a molded body 10. A transparent material 83 adjoins the respective end regions and sides of the molded body 10. The molded body 10 forms a planar surface with the surrounding material 83. A second glass layer 80 is arranged on the upper side of the molded body 10 and the adjacent material layer 83 and is connected to the display element.

As shown, the optoelectronic semiconductor component is located in a cavity 20 of the molded body 10. The cavity 20 is slightly larger, so that a small gap is formed in particular between the light-emitting upper side of the semiconductor body 30 and the material of the molded body 10. This gap is filled, for example, with air or another gas with a relatively low refractive index close to 1.0. This refractive index is significantly lower than the corresponding refractive index of the molded body 10. As a result, light emitted from the top of the component 30 is always refracted in the direction of the orthogonal axis as shown when it hits the interface between the air-filled gap and the molded body 10. The angle β between the intermediate space and the interface is smaller than the angle β′. The angle α is smaller than the angle α′.

In other words, the light entering the molded body is always refracted towards the vertical or orthogonal axis of the boundary surface. As a result, the minimum line width for the symbol element can be set by the distance D between the boundary surface in the recess of the molded body 10 and the upper surface of the molded body.

Another design option is the additional inclusion of a touch-sensitive sensor. FIG. 8 shows such an embodiment, in which the display element is combined with a touch-sensitive sensor 85 and arranged between two glass layers 90 and 91. The carrier 11 is applied to the glass layer 91 and the molded body 10b with its recess is arranged on the carrier 11. A supply line 85b is provided along a side edge of the molded body 10b, which leads to the surface of the molded body 10b. The touch-sensitive sensor 85 is arranged on this, which in turn is covered by a second glass layer 90. The touch-sensitive sensor 85 is designed, for example, as a capacitance-sensitive sensor. This allows a user to touch the glass pane 90 in the area of the touch-sensitive sensor 85, which detects the touch as a signal due to a change in capacitance and passes it on to an evaluation circuit, not shown here, to generate a further function.

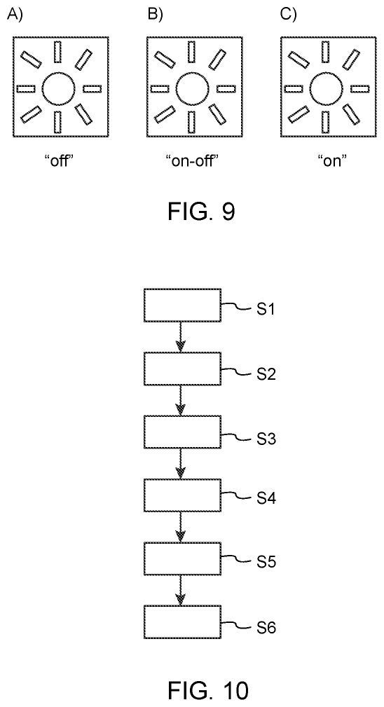

As in the previous example in FIG. 3, the molded body 10b is designed with absorber and diffuser particles. Due to the absorber and diffuser particles, the display element is visible to a user even when it is switched off, so that the position of the touch-sensitive sensor 85 is communicated to the user. FIG. 9 shows an embodiment of a stylized sun as a possible display and control element. The display and control element can be switched between three states, which are designated as “off”, “half-on” and “on”. In the first state, “off”, the optoelectronic components are switched off. The symbol is still clearly visible via the molded body. A user can therefore recognize the display and, in the case of a control element, also operate it. When the symbol is pressed or external parameters are changed, the state of the display and control element is switched from “off” to “half-on”. In this state, it is possible, for example, to activate only half of the respective optoelectronic components in order to generate a low level of illumination.

For example, only the optoelectronic components assigned to the lower half of the sun shown can be switched on. Alternatively, the components can also be operated with less current so that the intensity is lower. When the display and control element is operated or another external parameter is changed, the display and control element is switched from the “half-on” state to the “on” state. As a result, all optoelectronic components are activated equally and the symbol is displayed in its full form. Alternatively, the brightness of the symbol can also be changed. The special arrangement of the optoelectronic components under the symbol's molded body together with the diffuser layer ensures uniform illumination of the symbol even with different light intensities.

FIG. 10 illustrates a method for manufacturing a display or control element according to the proposed principle. In step S1, a carrier element is provided to which at least one optoelectronic component for generating light of a first wavelength is applied. The light emission side of the optoelectronic component faces away from the carrier element. To connect the optoelectronic component, the carrier element comprises a plurality of connecting leads which are arranged on the carrier element and connected to the contact pads of the component.

The production of such a carrier element can be carried out independently of the other steps in advance. The carrier element can be a flexible film made of a transparent plastic, but can also comprise a rigid carrier made of glass or another plastic, for example.

In a subsequent second step S2, a molded body is provided that forms a symbol element. For this purpose, the molded body comprises at least one recess on one side. The molded body thus forms a cavity. In this step, the molded body can also be manufactured separately in previous steps by means of an injection molding process. For this purpose, it is possible to produce each molded body individually or to produce a plurality of molded bodies by means of an injection molding process and then to separate them.

In a subsequent step S3, an adhesive is applied to the carrier element around the at least one optoelectronic component. Alternatively, the adhesive can also be applied to the side of the molded body comprising the recess and cavity, whereby the adhesive is not filled into the cavity or recess. The adhesive in the form of an adhesive layer or an adhesive film is used to subsequently attach the molded body to the carrier element. In a step S4, the molded body is now positioned on the carrier element so that the recess is located exactly above the at least one optoelectronic component.

The molded body is then placed on the carrier element in step S5 and glued to it or attached to it in step S6. The optoelectronic component is now located in the recess, whereby the recess itself is deeper and also somewhat larger than the optoelectronic component. As a result, there is a gap between the light-emitting side and the side surfaces of the at least one optoelectronic component and the material of the molded body.

The larger recess makes it possible to compensate for possible inaccuracies in the positioning of the molded body or tolerances in production during the manufacture of the body on the carrier element.

In an alternative embodiment, a carrier element is provided, to which the optoelectronic component is applied as in the previously written step S1. To create a gap according to the proposed principle, in this example a spacer foil with corresponding recesses in the area of the respective optoelectronic components is applied to the carrier and attached to it instead of a molded body. Like the carrier, the spacer foil is made of a transparent material. The recess in the spacer foil creates a space around the at least one optoelectronic component. At the same time, the spacer film comprises a greater thickness than the height of the optoelectronic component, so it protrudes beyond the component (s). The spacer film thus creates a gap around the area of the optoelectronic components.

A structured film is then provided. The structured film is designed in such a way that it contains a structure in the form of the symbol element. For example, diffuser particles, absorber particles, converter particles or a combination of these are incorporated into the structured film to form the symbol. The structured film is applied directly to the spacer film so that this structured film completely covers the space with the optoelectronic component in it. The structured film thus forms the molded body together with the spacer film.

In some aspects, the molded article can furthermore be roughened on some of its side walls. Alternatively, it is possible to apply a reflective layer to at least some of its side walls. However, such a reflective layer can also be arranged on the side of the molded body facing the carrier. It is also possible to form a reflective layer on the side walls in the recess of the molded body. The reflective layer at these points improves the efficiency of the display element, especially when it is switched on. Instead of the reflective layer, an absorbent layer can also be present at these points, so that the contrast in the switched-on or switched-off state of the display element and thus the symbol appears more clearly visible to a user in both states. The adhesive applied in step S3 can also be designed with reflective or absorbent particles.

### REFERENCE LIST

1, 1b, 1c Display element
10 Molded body
10b, 10c Molded body
11 Carrier
12, 13 Supply lines
16 Reflective layer
17 Reflective layer
20 Cavity, recess
30 Optoelectronic component
31, 32 Contact pads
40 Glass layer
81, 82 Glass layer
83 Material layer
85 Touch-sensitive sensor
85b Supply line
90 Glass layer

1. A display element, comprising:
a carrier element on which at least one optoelectronic component for generating light of a first wavelength is arranged with a light emission side, wherein the light emission side defines a main emission direction and the at least one optoelectronic component is connected to a plurality of connection lines on the carrier element;
a molded body forming a symbol element, which comprises at least one recess and is connected to the carrier element in such a way that the at least one optoelectronic component is arranged in the at least one recess, a space formed by the recess being present between the light exit side of the at least one optoelectronic component and the molded body;
wherein the symbol element formed by the molded body is visible to a user in a top view of the display element when the at least one optoelectronic component is switched off.

2. The display element according to claim 1, in which the carrier element comprises a plurality of optoelectronic components and the molded body forming the symbol element comprises a number of recesses corresponding to the plurality of optoelectronic components, in each case one optoelectronic component being arranged in a recess of the number of recesses corresponding to the plurality of optoelectronic components.

3. The display element according to claim 2, wherein a position of the plurality of optoelectronic components on the support element reproduces a shape of the symbol element.

4. The display element according to claim 1, wherein the support member comprises a plurality of optoelectronic components, and at least two of the plurality of optoelectronic components are disposed in the at least one recess of the molded body so that a space is formed between the light emitting side of the two optoelectronic components and the molded body forming the recess.

5. The display element according to claim 1, wherein side surfaces of the at least one optoelectronic component are spaced apart from a side surface of the recess, forming a gap.

6. The display element according to claim 1, wherein the space formed by the recess comprises a height of 20 μm to 100 μm and in particular a height in the range of 40 μm to 60 μm.

7. The display element according to claim 1, in which an edge length of the at least one optoelectronic component is in the range of less than 500 μm and in particular less than 200 μm and in particular less than 100 μm, wherein the at least one optoelectronic component is optionally designed as a horizontal light-emitting diode.

8. The display element according to claim 1, wherein the molded body comprises diffusion particles, in particular TiO2, Al2O3, PMMA or PC, which are substantially uniformly distributed.

9. The display element according to claim 1, wherein the molded body comprises diffusion particles whose concentration in the molded body also increases with increasing distance from the at least one optoelectronic component.

10. The display element according to claim 1, wherein the molded body comprises absorber particles, in particular soot particles, which are substantially uniformly distributed.

11. The display element according to claim 1, wherein the molded body comprises converter particles adapted to convert light emitted from the least one optoelectronic component into light of a different wavelength.

12. The display element according to claim 11, wherein a concentration of the converter particles in the molded body changes with increasing distance from the at least one optoelectronic component.

13. The display element according to claim 1, in which the side walls of the molded body are designed with a roughening or a reflective material.

14. The display element according to claim 1, in which a reflective layer is provided between the carrier element and the molded body, at least in partial regions.

15. The display element according to claim 1, wherein side walls of the recess comprise a reflective layer.

16. The display element according to claim 1, in which the molded body is attached to the carrier element by means of a reflective adhesive layer.

17. The display element according to claim 1, wherein the side of the recess opposite the light exit side of the at least one optoelectronic component comprises a curved shape.

18. The display element according to claim 1, in which the intermediate space is filled with a medium, in particular with gas, which comprises a lower refractive index than the material of the molded body.

19. The display element according to claim 1, in which the at least one optoelectronic component is designed to generate light of one color or to generate light of at least two colors, in particular green and/or red.

20. A method of manufacturing a display element comprising the steps of
providing a carrier element on which at least one optoelectronic component for generating light of a first wavelength is arranged with a light emission side, wherein the light emission side defines a main emission direction and the at least one optoelectronic component is connected to a plurality of connection lines on the carrier element;
providing a molded body which forms a symbol element, wherein the molded body comprises at least one recess;
arranging the molded body on the carrier element in such a way that the at least one optoelectronic component is arranged in the at least one recess;
fixing the molded body on the carrier element so that a gap formed by the recess is present between the light exit side of the at least one optoelectronic component and the molded body; and the symbol element formed by the molded body is visible to a user in a top view of the display element in a switched-off state of the at least one optoelectronic component.

21. The method according to claim 20, wherein providing a molded article comprises at least one of the following steps:
roughening of at least some of the side walls of the molded body;
forming a reflective layer on at least some of the side walls of the molded body;
forming an absorbent layer on at least some side walls of the molded body; and
forming a reflective layer on the side walls of the recess of the molded body.

22. The method according to claim 20, wherein the arranging of the molded article comprises:
applying of an adhesive, in particular an adhesive with reflective particles from the carrier element or the molded body.

23. The method according to claim 20, wherein providing the molded article comprises at least one of the following steps:
injecting molding of a molded part;
injecting molding of a large number of molded parts with subsequent separation;
introducing diffusor particles and/or converter particles during the injection molding process, whereby a concentration of the diffusor particles and/or converter particles changes with increasing distance from the LED and in particular increases.
